(19) United States
(12) Patent Application Publication
(10) Pub. No.: US 2006/0249805 A1
(43) Pub. Date: Nov. 9, 2006

(54) Shielding Layer outside the Pixel Regions of Optical Device and Method for Making the Same

(76) Inventors: Hsin-Wei Lin, Kao-Hsiung Hsien (TW); Chien-Hao Chen, Tai-Nan City (TW); En-Ting Liu, Kao-Hsiung City (TW); Der-Yu Chou, Miao- Li Hsien (TW)

Correspondence Address: NORTH AMERICA INTELLECTUAL PROPERTY CORPORATION, P.O. BOX 506, MERRIFIELD, VA, 22116, US

(21) Appl. No.: 10/908,219

(22) Filed: May 3, 2005

(51) Int. Cl. H01L 31/0232

(52) U.S. Cl. 257/435

(57) ABSTRACT

A shielding layer outside a sensing region I of a CMOS image sensor includes a stack of a first monochromatic color filter layer and a second monochromatic color filter layer. Such a two-layered monochromatic color filter acts as a shielding layer, and the amount of black photoresist needed is decreased. Therefore, a process of CMOS image sensor fabrication is simplified and the cost of fabrication is decreased. The black pigment is prevented from remaining and causing contamination.

### BACKGROUND OF INVENTION

1. Field of the Invention

The present invention is related to a shielding layer outside a pixel region of an optical device and a method for forming the same, and particularly, related to a shielding layer outside a sensing region of a CMOS device and a method for forming the same.

2. Description of the Prior Art

A complementary metal-oxide semiconductor (CMOS) image sensor is fabricated with a conventional CMOS fabricating processes. Therefore, the CMOS image sensor can easily be integrated with its control circuitry. Thus the cost of the CMOS image sensor is cheaper than a charge-coupled device. In addition, the CMOS image sensor also has advantages of small size, high quantum efficiency, and low read-out noise.

The CMOS image sensor separates (or classifies) incident light into a combination of light of different wavelengths. The light of different wavelengths are received by respective sensing elements and are transferred into digital signals of different intensities. For example, the CMOS image sensor can consider incident light as a combination of red, blue, and green light. Those wavelengths are subsequently received by photodiodes, and then transformed into digital signals. However, in order to separate incident light, a monochromatic color filter array (CFA) must be set above every optical sensor element.

In addition, in order to decrease noise, all light received by the CMOS image sensor should come from the CFA. In other words, light coming from intervals between monochromatic color filters and that coming from regions outside the sensing regions should be blocked. Please refer to FIG. 1. FIG. 1 is a sectional view of a conventional CMOS image sensor. In FIG. 1, a region I that includes a CFA, including monochromatic color filters 28, 30, 32, is a sensing region, and a left side of the sensing region I is the peripheral circuit region II which is outside the sensing region. As shown in FIG. 1, there is a patterned metal layer 14, so as to shield sensing elements 32, 34, 36 on a semiconductor substrate 40, from light scattered from the intervals of the CFAs 28, 30, 32. In another words, only on the regions beneath the intervals of the CFAs 28, 30, 32 is the metal using for shielding. Outside the CMOS sensing region I, there are shielding elements 22 to block light from regions outside the sensing region I. In addition, there are metal pads 24 for connecting outside the sensing region I. Since the metal pad 24 can shield light, there is no shielding element above the metal pad 13.

In conventional fabrication processes, after the base elements, such as the metal layer 14 and the planar layer 20, are formed, a CFA can be formed on the nitride layer 12. In order to form the CFA, a first monochromatic color filter layer made by photosensitive resin is formed. Following that, an exposing and developing process is applied on the monochromatic color filter layer to obtain a desired pattern, and then dyeing of the patterned monochromatic color filter layer with a first color is performed, so as to form a patterned first monochromatic color filter layer 26. Alternatively, photoresist dyed with the first color can also be used to form a first monochromatic color filter layer, after which an exposing and developing process is performed on it so as to form the patterned first monochromatic color filter layer 26. After the first monochromatic color filter layer 26 is formed, a curing process may be performed to strengthen the first monochromatic color filter layer 26. After the first monochromatic color filter 26 is formed, the process above is repeated to form a patterned second monochromatic color filter layer 28, and a patterned third monochromatic color filter layer 30. Those monochromatic color filters 26, 28, 30 all together form the CFA.

After the CFA is formed, a shielding layer is formed on the peripheral circuit region 11, which is outside the sensing region I, with similar process. In other words, a black photosensitive material layer is formed outside the sensing region I, and is then exposed and developed, so as to form a shielding layer 22 impervious to light. At last, an insulation layer 16 is formed on shielding layer 22, and the CFAs 26, 28, 30, to facilitate the fabrication of the lens 18. Parts of the insulation layer 16 are then removed to expose the metal pads 24 and other regions that need to be exposed. In addition, a metal pad 24 may not exist in the peripheral region II due to a different layout design. In such a case, the shielding layer 22 should be able to cover the whole peripheral circuit region II, which is outside the sensing region I.

Even though a shielding layer of a conventional CMOS image sensor is able to shield lights efficiently, a black photoresist material is expensive and the black pigment can cause problems. In addition, only the shielding layer is made of the black photoresist, therefore an extra exposing, developing and curing process and an extra mask is needed to form the shielding layer 22. As a result, a more economic and convenient shielding layer is needed to decrease the fabrication cost of the CMOS image sensor.

### SUMMARY OF INVENTION

An object of the claimed invention is to provide an improved shielding layer in an optical device and a method for forming the same, so as to decrease the cost of forming a shielding layer outside the sensing region of a CMOS image sensor.

According to the claims of the present invention, a shielding layer of an optical device is disclosed. The optical device is a CMOS image sensor, and the shielding layer is formed on a semiconductor substrate. In addition, the shielding layer includes a stack of a first monochromatic color filter layer and a second monochromatic color filter layer.

The device according to the present invention and the CFA can be formed at the same time using the same mask according to the method of the present invention. Therefore no extra mask is needed. In addition, the device according to the present invention does not include black photoresist. Therefore, the present invention can avoid the problem of remaining black pigment and decrease the fabrication cost.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a sectional view of a conventional CMOS image sensor.

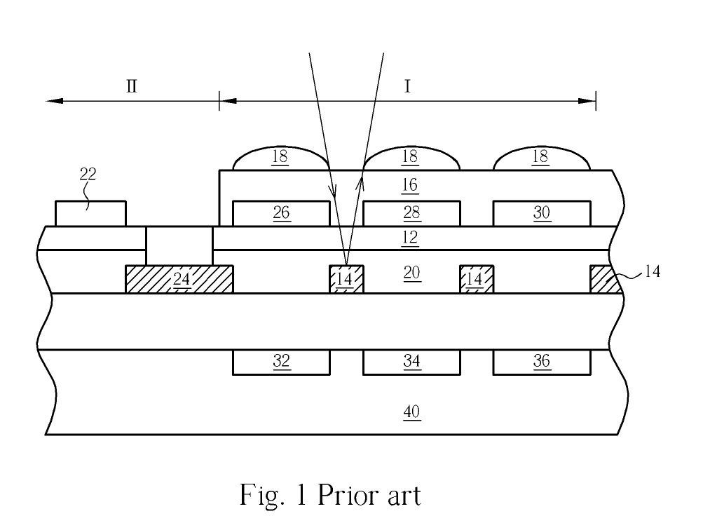

FIG. 2 is a sectional view of a CMOS image sensor according to the present invention.

FIG. 3 is a sectional view of the CMOS image sensor of FIG. 2.

FIG. 4 is a sectional view of a CMOS image sensor of FIG. 2.

FIG. 5 is a graph illustrating ranges of light that can pass through red, green, and blue monochromatic color filters.

FIG. 6 is a schematic view of the structure of an LCoS illustrating an embodiment of the present invention.

### DETAILED DESCRIPTION

Compared to a conventional shielding layer of an optical device, the shielding layer according to the present invention not only can shield light efficiently but also has the advantage of low fabrication cost. In other words, fabricating the shielding layer according to the present invention needs fewer masks, no black photoresist, and thus is able to avoid the contamination of black pigment.

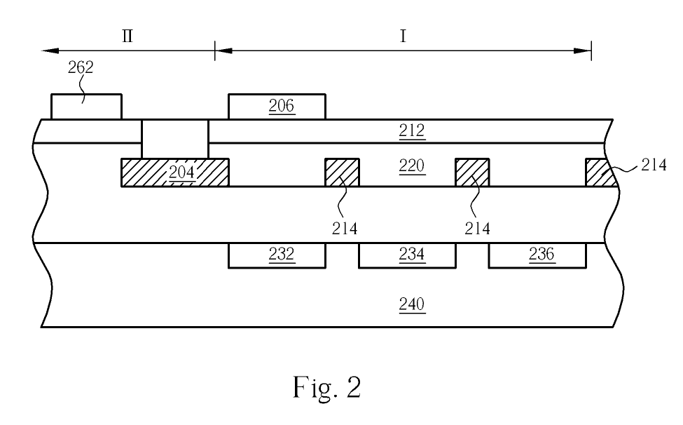

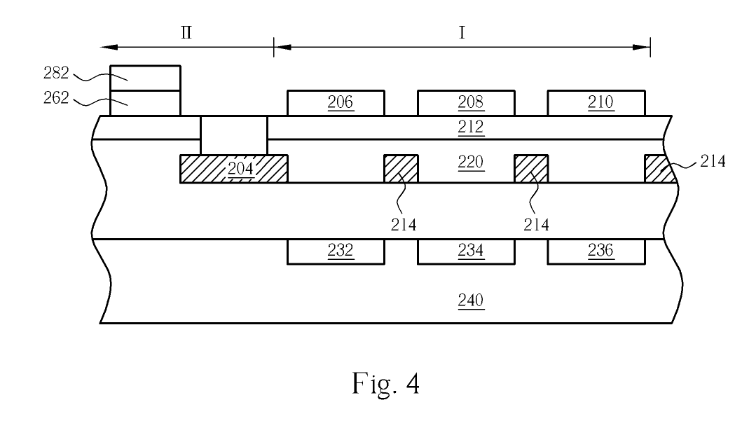

Consider a CMOS image sensor for example regarding the preferred embodiment of the present invention. Please refer to FIG. 2 to FIG. 4. FIG. 2 to FIG. 4 are sectional views of the CMOS image sensor. FIG. 2 to FIG. 4 illustrate a preferred embodiment for fabricating the according to the method of the present invention. As shown in FIG. 2, the CMOS image sensor can be divided into a sensing region I that senses incident lights, and a peripheral circuit region II outside the sensing region I. The sensing region I includes color filter array (CFA) and sensing elements 232, 234, 236 on the substrate 240. Before fabricating the shielding layer according to the present invention, the sensing elements 232, 234, 236 and other elements under the CFA are formed. Among those elements, a patterned metal layer 214 is formed under where the CFA will be formed. The patterned metal layer 214 is used to prevent light from being scattered through the intervals of the CFA. Therefore the pattern of the metal layer is dependent on the pattern of the CFA, and metal only exists in areas under the intervals of the CFA. In addition, a metal pad 204 may be formed on the peripheral circuit region II according to requirements. After the metal layer 214, the metal pad 204, and other metal interconnects are formed, a planar layer 220 is formed on the metal layer 214 so as to facilitate the performing of the subsequent process. Following that, a nitride layer 212 is alternatively formed on the planar layer 220 as a passivation layer.

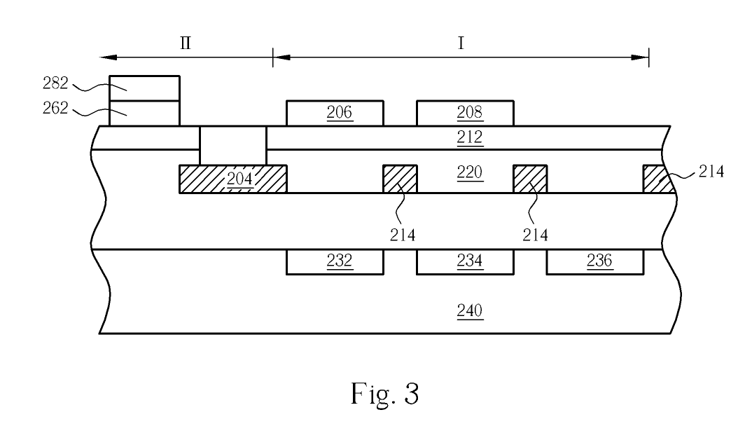

After the above process is completed, the shielding layer according to the present invention is formed. According to the present invention, while forming the first monochromatic color filter layer 206 in the sensing region I, another first monochromatic color filter layer 262 is formed in the peripheral circuit region II simultaneously. Following that, as shown in FIG. 3, while forming a second monochromatic color filter layer 208 in the sensing region I, another second monochromatic color filter layer 282 is formed outside the peripheral circuit region II simultaneously, and the second monochromatic color filter layer 282 is stacked onto the first monochromatic color filter layer 262 so as to form the shielding layer according to the present invention. Lastly, as shown in FIG. 3, a third monochromatic color filter layer 210 is formed in the sensing region I so as to complete the fabrication of the CFA.

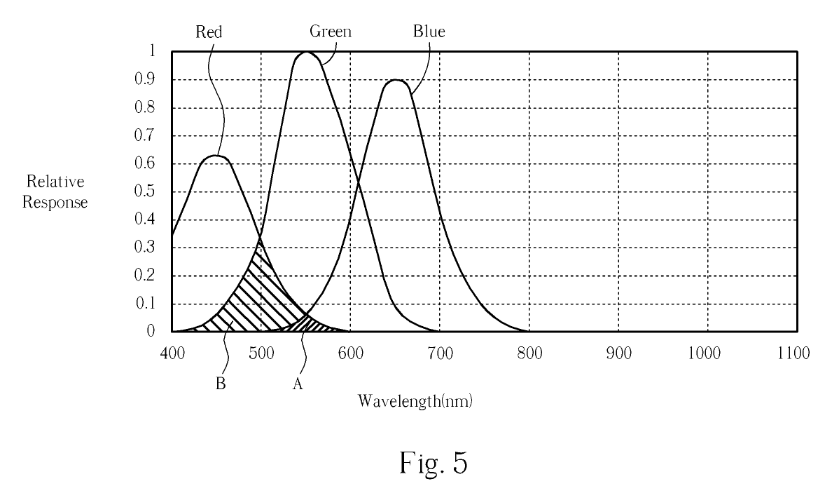

The stack of the first monochromatic color filter layer 262 and the second monochromatic color filter layer 282 is the shielding layer according to the present invention. Please refer to FIG. 5. FIG. 5 is a graph illustrating the wavelengths of light that can pass through red, green, and blue monochromatic color filters. According to FIG. 5, there is only a small range of light, shown as area A, that can pass through the red monochromatic color filter and then pass through the blue monochromatic color filter. In other words, a stack of a red monochromatic color filter and a blue monochromatic color filter can filter out most visible light. Therefore, when the first monochromatic color filter layer 262 and the second monochromatic color filter layer 282 are a red monochromatic color filter and a blue monochromatic color filter respectively, the shielding layer according to the present invention can shield most visible light. As a result, the shielding layer according to the present invention is able to replace the conventional shielding layer made of black photoresist.

In addition, monochromatic color filters of other colors can also be stacked together to form a shielding layer. For example, when the first monochromatic color filter layer 262 and the second monochromatic color filter layer 282 are a red monochromatic color filter and a green monochromatic color filter respectively, there is only a range of light, shown as area B, that can pass through the shielding layer. Therefore, a shielding layer constructed with a red monochromatic color filter and a green monochromatic color filter is also workable, even though its performance may not be as good as that constructed with a red monochromatic color filter and a blue monochromatic color filter. Similarly, a single monochromatic color filter can also be used as a shielding layer. However, the performance of the single layer is limited, and thus is not as good as the two-layered one. In addition, red, green, and blue monochromatic color filters can all be stacked together to form a three-layered shielding layer. This kind of shielding layer has the best shielding performance. However, the more layers used, the thicker the shielding layer. If the shielding layer is too thick, there can be problems in the subsequent packing and wiring processes. Therefore a two-layered shielding layer is the preferred embodiment of the present invention for its better performance in light shielding and thickness. However, all these are design considerations that can change to meet the requirements of specific products, constructions, and layout designs, so as to achieve the best arrangement.

It has to be noted that the fabrication process of the shielding layer is not limited to the above process. For example, the shielding layer according to the present invention can be formed after the monochromatic color filters of the CFA are formed. In such a case, the using of black photoresist is also avoided and thus contamination is reduced.

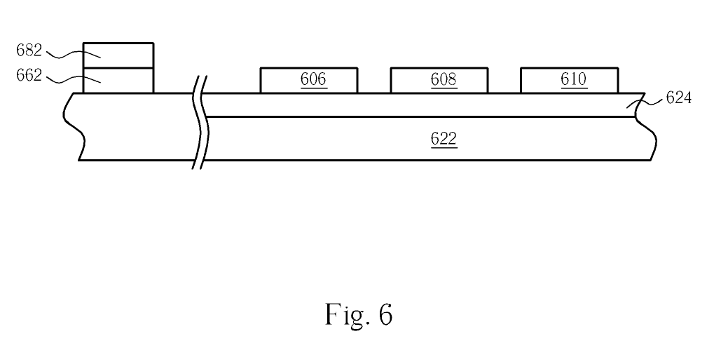

In addition to the CMOS image sensor, some liquid crystal on silicon (LCoS) displays also use CFAs to separate light. Please refer to FIG. 6. FIG. 6 illustrates a sectional of the lower part of an LCoS display. As shown in FIG. 6, an LCoS includes a semiconductor substrate 622 and a pixel electrode 624 that can also serve as a reflector. There is a CFA composed of a plurality of monochromatic color filters 606, 608, 610. A pixel region of the LCoS includes the monochromatic color filters 606, 608, 610. Outside the pixel region, a shielding layer according to the present invention, that is the stack of a first monochromatic color filter layer 662 and a second monochromatic color filter layer 682, is formed to prevent light reflected by the pixel electrode 624 from emitting to the region outside the pixel region.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An optical device, the optical device comprising:
a substrate comprising an optically active region and a peripheral circuit region;
a plurality of optical elements disposed in the optically active region;
at least one insulation layer covering the optical elements;
a monochromatic color filter array disposed on the insulation layer to separate colors of light; and
a shielding layer comprising a stack of a first monochromatic color filter layer and a second monochromatic color filter layer disposed in the peripheral circuit region.

2. An optical device according to claim 1, wherein the optically active region is a sensing region, and the optical device is a complementary metal-oxide semiconductor image sensor.

3. An optical device according to claim 2, wherein the optical elements comprise a plurality of photodiodes.

4. An optical device according to claim 3, wherein the monochromatic color filter array comprises three monochromatic color filters arranged in a grid, the monochromatic color filters corresponding to the photodiodes respectively.

5. An optical device according to claim 1, wherein the optically active region is an optical display region, and the optical device is a liquid crystal on silicon display.

6. An optical device according to claim 5, wherein the optical elements comprise a plurality of pixel electrodes.

7. An optical device according to claim 6, wherein the monochromatic color filter array comprises three monochromatic color filters arranged in a grid, the monochromatic color filters corresponding to the pixel electrodes respectively.

8. An optical device according to claim 1, wherein the monochromatic color filter array comprises red, green, or blue monochromatic color filters.

9. An optical device according to claim 1, wherein the first monochromatic color filter layer and the second monochromatic color filter layer are red and green monochromatic color filter layer respectively.

10. An optical device according to claim 1, wherein the shielding layer further comprises a third monochromatic color filter layer disposed on the first and the second monochromatic color filter layers.

11. A method for making an optical device, which is deposited on a substrate, which comprising an optically active region and a peripheral circuit region, the method comprising:
forming a first monochromatic color filter layer in the a peripheral circuit region while forming another first monochromatic color filter layer in the optically active region; and
forming a second monochromatic color filter layer on the first monochromatic color filter in the a peripheral circuit region to form a shielding layer, while forming another second monochromatic color filter layer in the optically active region.

12. A method according to claim 11, wherein the optically active region is a sensing region, and the optical device is a complementary metal-oxide semiconductor image sensor.

13. A method according to claim 11, wherein the optical active region comprises a plurality of photodiodes, a plurality of insulators deposited between the photodiodes, and a monochromatic color filter array.

14. A method according to claim 13, wherein the monochromatic color filter array comprises a plurality of monochromatic color filters disposed in a predetermined arrangement, the monochromatic color filters corresponding to the photodiodes respectively.

15. A method according to claim 14, wherein the predetermined arrangement comprises a grid arrangement or honeycomb arrangement.

16. A method according to claim 13, wherein the monochromatic color filter array comprises a blue monochromatic color filter layer, a green monochromatic color filter layer and a red monochromatic color filter layer.

17. A method according to claim 13, wherein the first monochromatic color filter layer and the second monochromatic color filter layer in the optically active region is used to form the monochromatic color filter array.

18. A method according to claim 11 further comprises forming a third monochromatic color filter layer on the second monochromatic color filter in the a peripheral circuit region to form a shielding layer, while forming another third monochromatic color filter layer in the optically active region.
